(19) United States
(12) Patent Application Publication
(10) Pub. No.: US 2014/0311549 A1
(43) Pub. Date: Oct. 23, 2014

(54) SOLAR-POWER ENHANCING MODULE AND SUN TRACKING SYSTEM THEREOF

(71) Applicant: YUN-MIN WANG, Taipei City (TW)

(72) Inventor: YUN-MIN WANG, Taipei City (TW)

(21) Appl. No.: 14/245,077

(22) Filed: Apr. 4, 2014

(30) Foreign Application Priority Data
Apr. 22, 2013 (TW) 102207299

(51) Int. Cl. H01L 31/052; H01L 31/042

(52) U.S. Cl. CPC H01L 31/0525; H01L 31/0422; H02S 20/00
USPC 136/246

(57) ABSTRACT

The present disclosure provides a solar-power enhancing module comprising: a base plate and a plurality of photovoltaic units disposed on the base plate. Each of the photovoltaic units comprises: a solar panel, a pair of first reflector boards and a pair of second reflector boards. The two first reflector boards are disposed at two opposite sides of the photovoltaic unit. Each of the first reflector boards has a first reflector face at the front thereof. The two second reflector boards are disposed at the other two sides of the photovoltaic unit. Each of the second reflector boards has a second reflector face at the front thereof.

### BACKGROUND OF THE INVENTION

1. Field of the Invention

The present disclosure relates to a solar-power enhancing module; in particular, to a solar-power enhancing module having a solar base plate formed with a pair of first reflector boards and a pair of second reflector boards

2. Description of Related Art

When collecting solar energy, the efficiency of the solar modules is limited by production material, assembly structure and other technical limitations. Some energy is lost due to the inability of solar panels to convert light from the entire range of frequencies of solar light into electricity. Other energy lost results from material and structure of the solar module. The latter account for a larger portion of wasted energy.

However, a typical solar power device disposes the solar panels outdoors, converts solar light into electrical energy in the form of direct current, uses an inverter to convert the direct current into an alternating current, and then stores the alternating current in batteries or directly transmit the alternating current to the electrical device for use. In order to overcome the problem encountered by the abovementioned solar batteries and increase the output of the solar batteries, the industry currently has proposed several solutions to improving efficiencies of solar batteries, including: adjusting the incident angle of sunlight, increasing the reception area of the solar panel, using different material for solar batteries, adjustments to inverters, etc. These solutions are effective but costs such as particular materials and assembly processes renders the solutions economically impractical.

Hence, the present inventor believes the above mentioned disadvantages can be overcome, and through devoted research combined with application of theory, finally proposes the present disclosure which has a reasonable design and effectively improves upon the above mentioned disadvantages.

### SUMMARY OF THE INVENTION

The object of the present disclosure is to provide a solar-power enhancing module and a sun tracking system thereof, which improves the light collecting efficiency and saves installation costs by using a pair of first reflector faces and a pair of second reflector faces to focus more light on the solar panel.

The present disclosure provides a solar-power enhancing module comprising: a base plate and a plurality of photovoltaic units disposed on the base plate. Each of the photovoltaic unit includes: a solar panel, a pair of first reflector boards and a pair of second reflector boards. The two first reflector boards are arranged on opposite sides of the photovoltaic unit. Each of the first reflector boards has a first reflector face at the front thereof. The two second reflector boards are arranged on the other two sides of the photovoltaic unit. Each of the second reflector boards has a second reflector face at the front thereof.

Another object of the present disclosure is to provide a sun tracking system having a solar-power enhancing module, which adjusts the incidence angle between the solar panels and the light by using a plurality of drive units to rotate and move the carrying unit and a plurality of support units.

The present disclosure also provides a sun tracking system having a solar-power enhancing module comprising: at least one solar-power enhancing module and a sun tracking system. Each of the solar-power enhancing modules comprises: a base plate and a plurality of photovoltaic units disposed on the base plate. Each of the photovoltaic unit includes: a solar panel, a pair of first reflector boards and a pair of second reflector boards. The two first reflector boards are arranged on opposite sides of the photovoltaic unit. Each of the first reflector boards has a first reflector face at the front thereof. The two second reflector boards are arranged on the other two sides of the photovoltaic unit. Each of the second reflector boards has a second reflector face at the front thereof. The sun tracking system includes: a support unit, a carrying unit and at least one drive unit. The support unit is fixed on a surface. The carrying unit is disposed at the support unit for carrying at least one solar-power enhancing device. At least one drive unit is disposed on the support unit for driving the carrying unit and the support unit to rotate.

The present disclosure has the following advantages. The provided solar-power enhancing module can increase the intensity of light incident on the photovoltaic units by using the design of “the first reflector faces and the second reflector faces reflecting and focusing light.” By this configuration, the cost of assembling the solar panel is reduced, improving the value of the solar devices.

In order to further the understanding regarding the present disclosure, the following embodiments are provided along with illustrations to facilitate the disclosure of the present disclosure.

### BRIEF DESCRIPTION OF THE DRAWINGS

FIG. 1 shows a perspective view according to a first embodiment of the present disclosure;

FIG. 2 shows a schematic diagram of reflector boards according to a first embodiment of the present disclosure;

FIG. 3 shows an exploded view according to a first embodiment of the present disclosure;

FIG. 4A shows a first optical schematic diagram according to a first embodiment of the present disclosure;

FIG. 4B shows a second optical schematic diagram according to a second embodiment of the present disclosure;

FIG. 5 shows a schematic diagram of a base plate and photovoltaic units according to a first embodiment of the present disclosure;

FIG. 6 shows a schematic diagram of another implementation according to a first embodiment of the present disclosure;

FIG. 7 shows a schematic diagram of reflector boards according to a first embodiment of the present disclosure; and

FIG. 8 shows a schematic diagram of a sun tracking system according to a second embodiment of the present disclosure.

### DETAILED DESCRIPTION OF THE PREFERRED EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

### First Embodiment

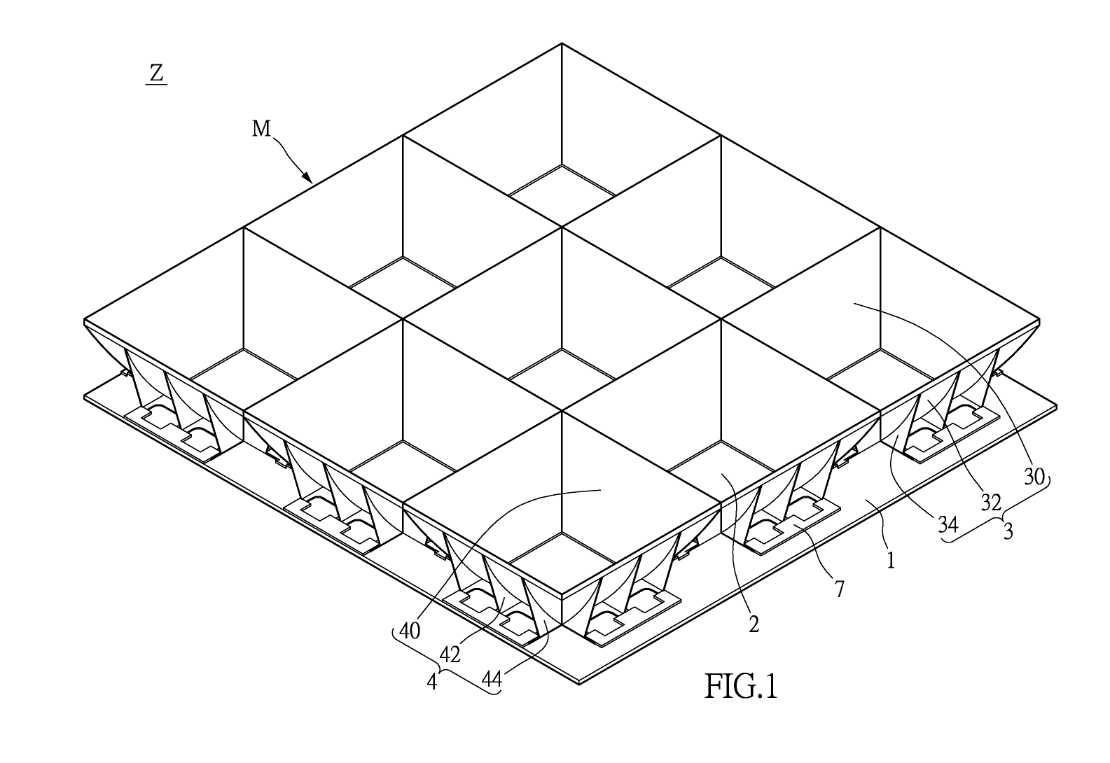

FIG. 1 shows a perspective view according to a first embodiment of the present disclosure. As seen in the figure, the present embodiment provides a solar-power enhancing module Z comprising: a base plate 1 and a plurality of photovoltaic units M. Each of the photovoltaic units M comprises: a solar panel 2, two first reflector boards 3 and two second reflector boards 4. The solar panel 2 is disposed on the base plate 1. The two first reflector boards 3 are disposed at two opposite sides of the solar panel 2 and on the base plate 1. Each of the first reflector boards 3 has a first reflector face 30 at the front (light receiving face) thereof. First support frames 34 support the first reflector boards 3. Additionally, two second reflector boards 4 are disposed at the other two sides of the panel 2 and on the base plate 1. Each of the second reflector boards 4 has a second reflector face 40. Each of the second reflector board 4 has a second support frame 44 supporting the backside thereof. The second support frames 44 support the second reflector boards 4. It must be noted that the two first reflector boards 3 and the two second reflector boards 4 surrounding a solar panel 2 can be a joined unit. The joined unit (two first reflector boards 3 and two second reflector boards 4) can be combined by support frames, screws, latches, etc.

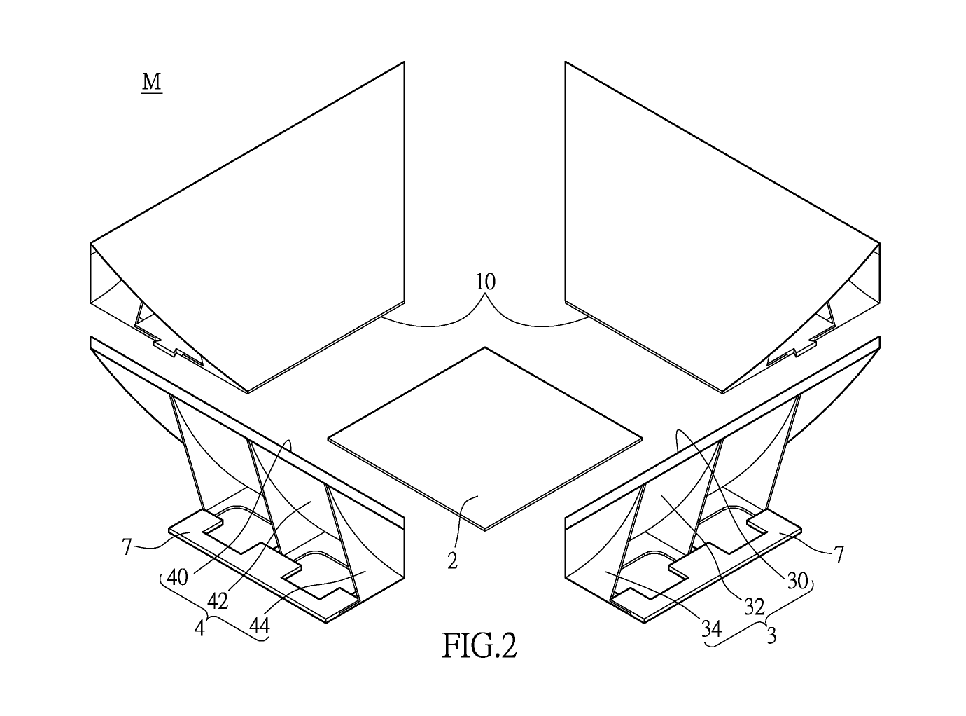

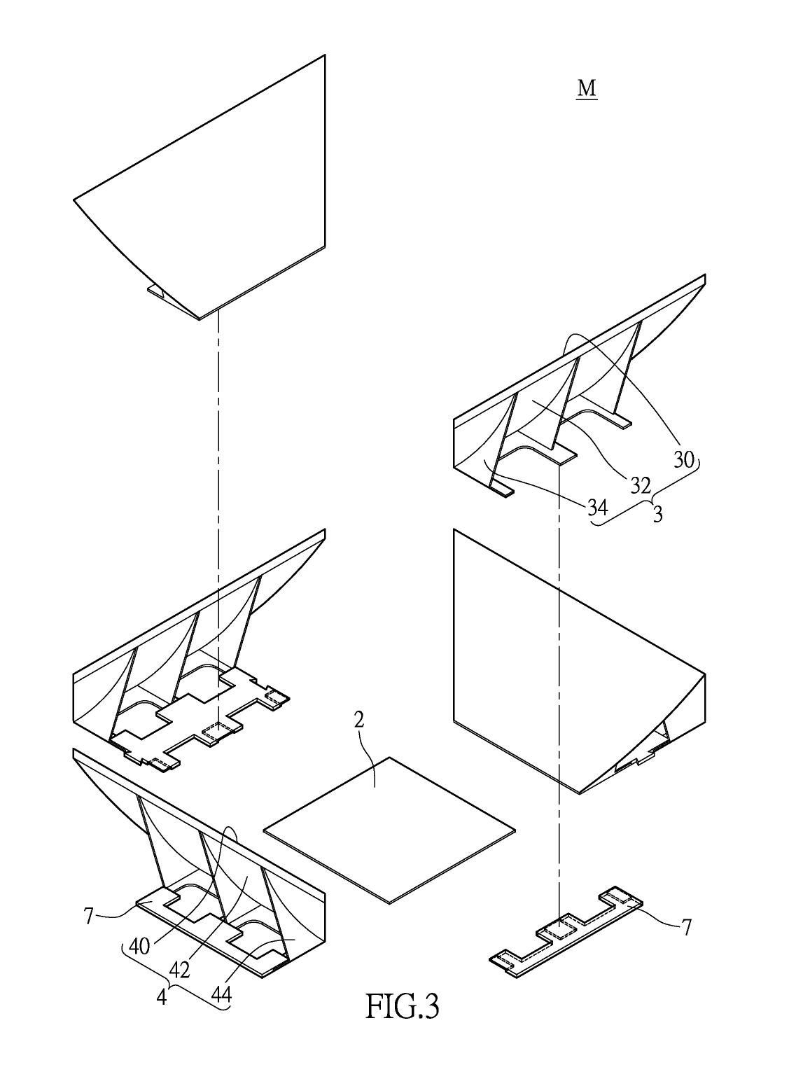

Referring to FIG. 1 to FIG. 3, the front faces of the first reflector boards 3 each have a first reflector face 30 and the front faces of the second reflector boards 4 each have a second reflector face 40. The first reflector faces 30 and the second reflector faces 40 can be each a smooth flat surface, curved surface, or a combination of smooth and flat surfaces. A concavely curved surface has preferred light focusing effect. Moreover, the backsides of the first reflector boards 3 each have a first unlit face 32, and the backsides of the second reflector boards 4 each have a second unlit face 42. The first unlit faces 32 and the second unlit faces 42 are each made of non-translucent material, and connected to the respective first support frame 34 or the second support frame 44. The first support frames 34 and the second support frames 44 support the first reflector boards 3 and the second reflector boards 4.

It must be noted that in the present embodiment, the first reflector boards 3 and the second reflector boards 4 can be made of plastic, synthetic fiber, glass, metal, etc. However, the material of the first reflector boards 3 and the second reflector boards 4 is not limited to the above. The first reflector boards 3 and the second reflector boards 4 can be integrally formed as one body, i.e. made of one mold. Alternately, when the first reflector boards 3 and the second reflector boards 4 are formed independently as separate pieces, The backsides of the first reflector boards 3 and the backsides of the second reflector boards 4 at the periphery of the solar-power enhancing module Z, and the backsides of the first reflector boards 3 and the backsides of the second reflector boards 4 not at the periphery of the solar-power enhancing module Z can be fixed by the first support frames 34, the second support frames 44, screws, latches and other engagement units for fixing the first reflector boards 3 and the second reflector boards 4.

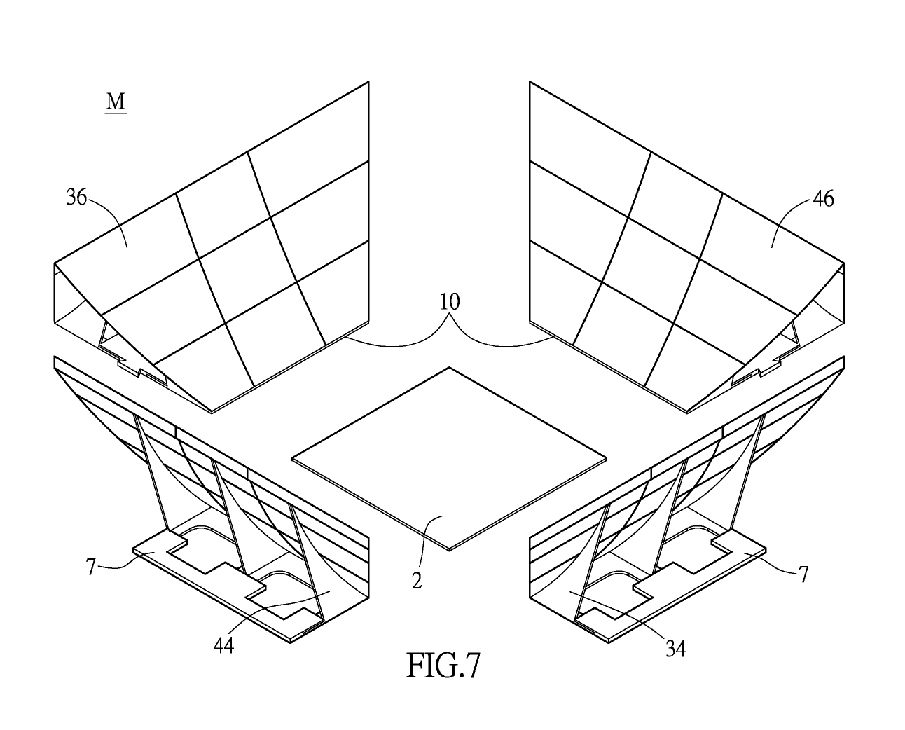

Additionally, the first reflector boards 3 and the second reflector boards 4 can each include a plurality of smaller reflector boards (refer to FIG. 7). In other words, each of the first reflector boards 3 and each of the second reflector boards 4 are respectively formed by a plurality of first small reflector boards 36 and a plurality of second small reflector boards 46. Specifically, the user can disassemble or assemble the first reflector boards 3 and the second reflector boards 4 for achieving different reflecting needs. When the first reflector boards 3 and the second reflector boards 4 are each formed by a plurality of small boards, the backsides of the first reflector boards 3 and the backsides of the second reflector boards 4 still require the first support frames, the second support frames, screws, latches, or other engagement units for fixing the first reflector boards 3 and the second reflector boards 4. However, the engagement units of the present disclosure are not limited thereto.

The surfaces of the first reflector boards 3 and the second reflector boards 4 are treated for forming smooth reflective surfaces. The surface treatment can be plating, surface coating, grinding, polishing, chemical vapor deposition, adhering a high reflectance material, physical vapor deposition, etc. such that the first reflector boards 3 and the second reflector boards 4 have smooth and glossy surfaces. Specifically, dust-proof and water-proof protective layers can be coated on the first reflector faces 30 and the second reflector faces 40 of respectively the first reflector boards 3 and the second reflector boards 4 for protecting the first reflector faces 30 and the second reflector faces 40 from dust or water, preserving the smoothness and glossiness of the surfaces of the reflecting faces and ensuring efficiency of reflection.

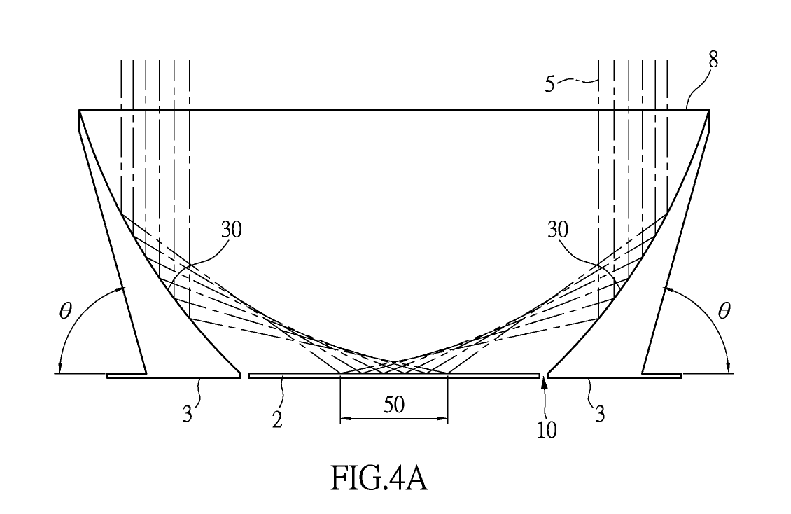

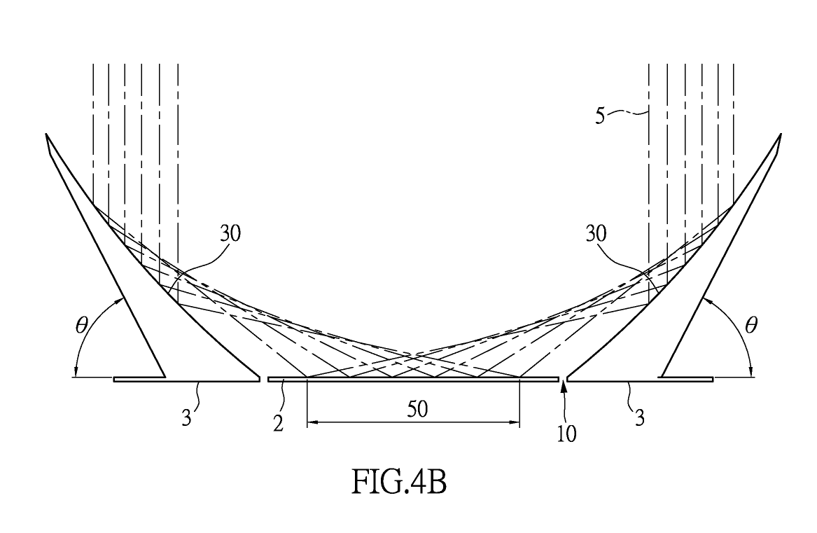

Moreover, a transparent hood 8 of high light transmittance can be disposed above the two first reflector boards 3 and the two second reflector boards 4 of each of the photovoltaic units M for preventing dust, humidity, contaminants, etc. from adhering to the reflector boards (refer to FIG. 4A). This makes the reflector boards easier to clean and maintain. Additionally, the base plate 1 can be formed with grooves 10 for draining water on the base plate 1 and the solar panel 2, so that water does not accumulate.

Referring to FIG. 1, FIG. 4A and FIG. 4B. The reflector boards 3 and the reflector boards 4 each have an included angle θ with the base plate 1. The included angle θ can be adjusted according to need but is smaller than 90 degrees. When light 5 reaches the first reflector faces 30 and the second reflector faces 40, the first reflector faces 30 and the second reflector faces 40 reflect the light 5 to the solar panel 2. Given that the surfaces of the first reflector faces 30 and the second reflector faces 40 are concave, the light 5 is focused and a light gathering area 50 can be formed on the solar panel 2. It must be mentioned that the radius of curvature of the first reflector boards 3 and the second reflector boards 4 can be adjusted according to need and can be flat surfaces, curved surfaces, or a combination of flat and curved surfaces. Concavely curved surfaces provide the best light focusing effects.

Specifically, referring to FIG. 1 and FIG. 4A, when the included angle θ between the first reflector board 3 and the base plate 1, or between the second reflector board 4 and the base plate 1, is greater, the angle of inclination of the first reflector faces 30 and the second reflector faces 40 is greater. The light 5 reaches the first reflector faces 30 and the second reflector faces 40, is reflected by the reflecting faces, and focused at the light gathering area 50. Given that the angle of incidence of the light 5 on the first reflector faces 30 and the second reflector faces 40 is large, the light 5 is reflected to a lower height at the opposite reflector board. Therefore, more solar energy is gathered per unit area on the solar panel 2.

Referring to FIG. 1 and FIG. 4B, when the included angle θ between the first reflector board 3 and the base plate 1, or between the second reflector board 4 and the base plate 1, is smaller, the angle of inclination of the first reflector faces 30 and the second reflector faces 40 is smaller, the angle of inclination of the first reflector faces 30 and the second reflector faces 40 is smaller. The light 5 reaches the first reflector faces 30 and the second reflector faces 40, is reflected by the reflecting faces, and focused at the light gathering area 50. Given that the angle of incidence of the light 5 on the first reflector faces 30 and the second reflector faces 40 is small, the light 5 is reflected to a higher height at the opposite reflector board. Therefore, less solar energy is gathered per unit area on the solar panel 2.

Additionally, the heights of the first reflector boards 3 and the second reflector boards 4 can be adjusted to adjust the size of the light gathering area 50. When the first reflector boards 3 and the second reflector boards 4 are higher, a smaller and more focused light gathering area 50 is formed. Conversely, when the first reflector boards 3 and the second reflector boards 4 are lower, a larger light gathering area 50 is formed. In other words, the height of each pair of first reflector boards 3 can be greater than, smaller than, or equal to the height of the respective pair of second reflector boards 4. In other words, the first reflector boards 3 and the second reflector boards 4 can be arranged at different heights according to whether the system uses a single-axis sun tracking, dual-axis sun tracking, or different magnifications.

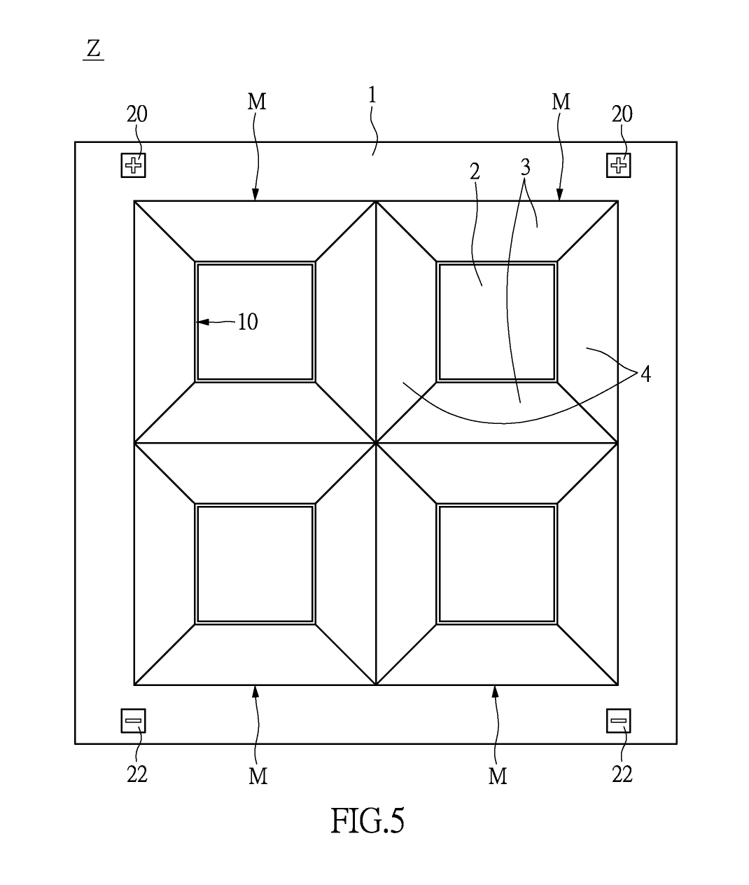

In the present embodiment (please refer to FIG. 5), the solar-power enhancing module Z comprises: a base plate 1 and four photovoltaic units M. Each of the photovoltaic units M comprises: a solar panel 2, two first reflector boards 3 and two second reflector boards 4. The first reflector boards 3 and the second reflector boards 4 are disposed on the base plate 1 in pairs. It must be noted that the first reflector boards 3 and the fourth reflector boards 4 are horizontally alternately arranged surrounding the solar panel 2. The lateral sides of the first reflector boards 3 and the lateral sides of the fourth reflector boards 4 are connected.

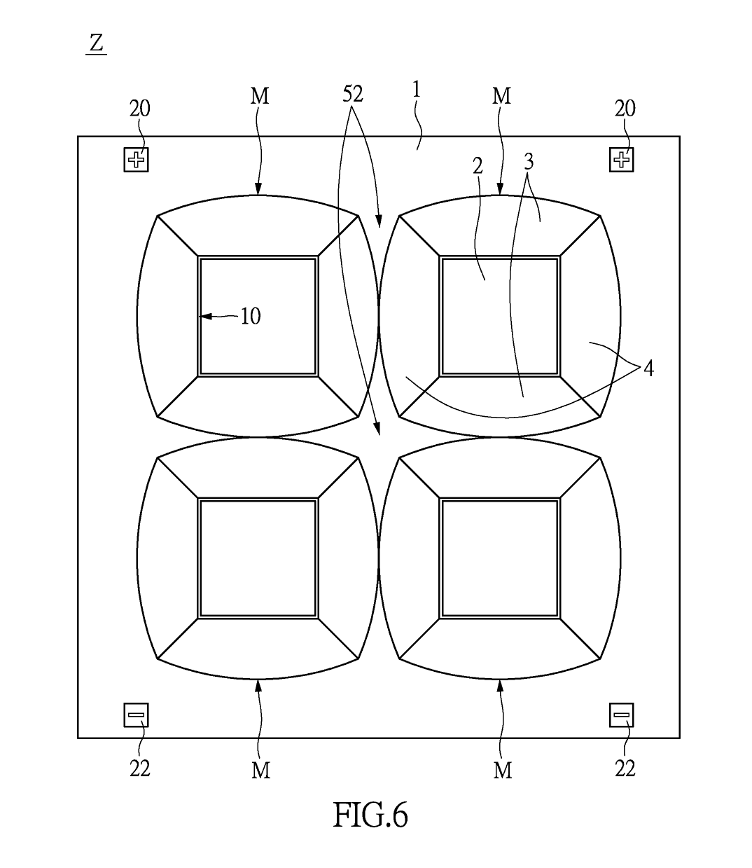

Referring to FIG. 6, another implementation of the present embodiment differs from the abovementioned embodiment (please refer to FIG. 5) in that the two first reflector boards 3 and the two second reflector boards 4 surrounding a solar panel 2 can be designed according to needs to have different magnifications. In other words, the first reflector boards 3 and the second reflector boards 4 can have different radii of curvature so that gaps 52 are defined between any of the neighboring first reflector board 3 and second reflector board 4. Obviously, in other implementations, the first reflector boards 3 and the second reflector boards 4 can have no gaps therebetween (tightly connected).

Specifically, adjacent reflector boards can be connected by a strip 7. The strips 7 are disposed under the first support frames 34 and the second support frames 44. Each of the strips 7 connects and fixes two adjacent support frames of the same side. By this method, the plurality of first reflector boards 3 and the plurality of second reflector boards 4 are connected, and plurality of first reflector faces 30 and the plurality of second reflector faces 40 are arranged the respective positions to form an array of reflector faces. Then, the arranged first reflector boards 3 and the second reflector boards 4 are disposed on the base plate 1 and fixed thereto by glue, soldering, screws, latching, inserts, etc. but is not limited thereto. The strips 7 of the present disclosure can each be a plastic body, a synthetic fiber body, a synthetic rubber body or a metal body but is not limited thereto.

The solar-power enhancing module Z of the present disclosure can be a fixed light gathering device. According to needs of each region, the long side of the solar-power enhancing module Z can be arranged along the direction of travel of the sun. The angle of inclination of the base plate 1 with respect to the horizontal plane can be arranged at a specific degree according to the angle of projection of the sunlight such that the solar-power enhancing device M can harvest the greatest amount of solar energy. It is worth noting that since the first reflector boards 3 and the second reflector boards can focus light, the surface area of the solar panel 2 does not have to be overly large. In the present embodiment, the surface area of the solar panels 2 amount to only about fifty percent of the surface area of the base plate 1. By this configuration, the cost of solar panels 2 is decreased. Moreover, the solar panels 2 can be arranged on the base plate 1 in arrays, and be connected in series, parallel or both to achieve greater outputs. A plurality of solar-power enhancing modules Z can be electrically connected in series, parallel or both to comply with voltage and current required by the user and achieve optimum output rate and facilitate maintenance.

In the present embodiment, the solar panel 2 can be an n-type semiconductor or a p-type semiconductor. The materials of n-type semiconductors and p-type semiconductors are for example elements from the Group XIV of the periodic table such as single crystal silicon, polysilicon, amorphous silicon, SiGe, the Groups III-V such as GaN, GaAs, GaP, InP, InGaP, or the Groups II-VI such as CdTe, CuInSe, CuInGaSe, etc. Additionally, organic dye sensitized solar cells or organic polymer semiconductor solar cells can be selected. Additionally, the solar-power enhancing module Z can include battery units (not shown in the figures), such as rechargeable batteries, electrically connected to the photovoltaic units M, for storing energy produced by the solar panels. To prevent electric energy stored in the battery unit from flowing back to the solar panels 2, valves can be arranged between the solar panels and the battery unit (not shown in the figures), such as diodes, other semiconductor units or electric circuits which allows flow of current in only one direction, to ensure that electric energy does not return to the solar panels 2 from the battery unit leading to damage of the circuits.

Referring to FIG. 5 and FIG. 6, the anode pin 20 and the cathode pin 22 of the solar panels 2 can be disposed at two opposite sides of the base plate 1. A benefit of this configuration is that if multiple solar-power enhancing modules Z are to be connected in series or parallel, the solar-power enhancing modules Z can be directly and conveniently connected, increasing the practicality and convenience of the solar-power enhancing modules Z.

For example, if the user intends to connect a plurality of solar-power enhancing modules Z in series, the anode pin 20 of one of the solar-power enhancing module Z needs only be connected to the cathode pin 22 of a second solar-power enhancing module Z by using wires. Then, the anode pin 20 of the second solar-power enhancing module Z is connected to the cathode pin 22 of a third solar-power enhancing module Z by using wires, and so on. Alternately, if the user intends to connect a plurality of solar-power enhancing modules Z in parallel, the solar-power enhancing modules Z need only be arranged side by side, the anode pins 20 of the solar-power enhancing modules Z are connected, and the cathode pins 22 of the solar-power enhancing modules Z are connected.

### Second Embodiment

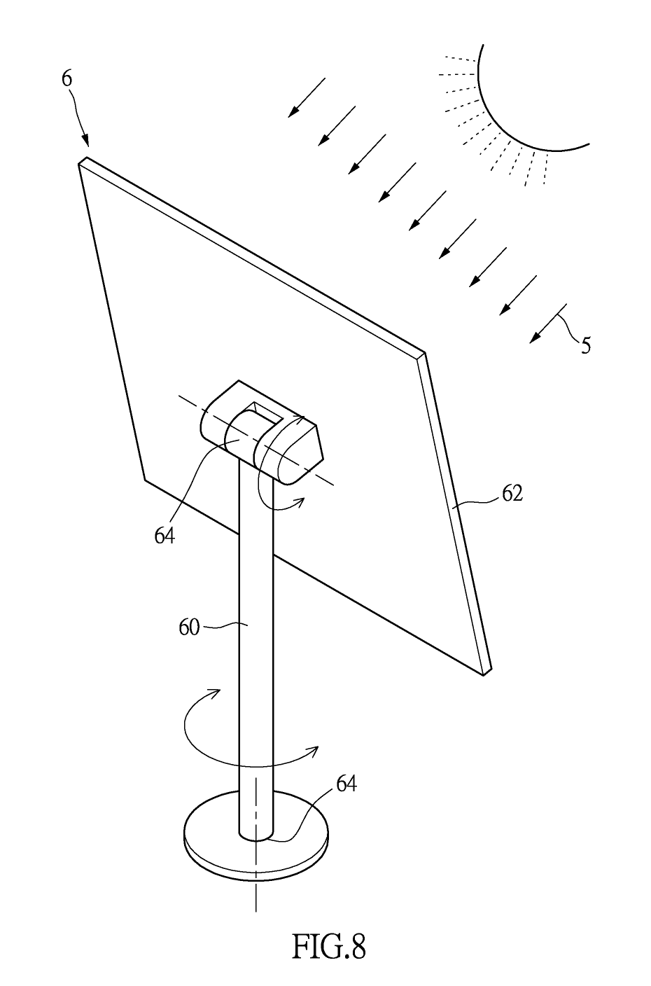

FIG. 8 shows a schematic diagram of a sun tracking system 6 according to a second embodiment of the present disclosure. As shown in the above figure, the second embodiment of the present disclosure provides a sun tracking system 6 having a solar-power enhancing module Z, comprising: at least one solar-power enhancing module Z and a sun tracking system 6. The at least one solar-power enhancing device M comprises: a base plate 1 and a plurality of photovoltaic units M disposed on the base plate 1. Each of the photovoltaic units M comprises: a solar panel, two first reflector boards 3 and two second reflector boards 4. The sun tracking system 6 comprises: a support unit 60, a carrying unit 62 and at least one drive unit 64.

Refer to the first embodiment for the solar-power enhancing module Z, which is not further detailed herein. The main difference between the second embodiment and the first embodiment of the present disclosure lies in that: in the second embodiment, the sun tracking system comprises a support unit 60, a carrying unit 62 and at least one drive unit 64. The support unit 60 is fixed on a surface. The carrying unit 62 is disposed on the support unit 60 for carrying at least one solar-power enhancing device M. The at least one drive unit 64 is disposed on the support unit 60, mainly for driving the carrying unit 62 and the drive unit 64 to rotate so as to adjust the incidence angle between the solar panels 2 and the light 5, reducing the angle of inclination between the light 5 and the reflector boards to increase light gathering efficiency (magnification) and the photovoltaic conversion rate of the solar panels.

In the present embodiment, the sun tracking system 6 has two drive units 64 for dual axis sun tracking. The drive units 64 are respectively disposed at two ends of the support unit 60, such that the carrying unit 62 and the support unit 60 can rotate. However, given that the cost of a dual axis sun tracking system is higher, the present embodiment can also have only one drive unit 64 for single axis sun tracking. The drive unit 64 can be a pivot rod, a guide wheel or a drive shaft. Obviously, in other implementations, the drive unit 64 can be manually operated such that the user can adjust the drive unit 64 to the appropriate positions at specific times. This design is suitable for places not willing to install overly expensive sun tracking systems 6.

### Possible Advantages of the Embodiments

The present disclosure has the following advantages. The provided solar-power enhancing device can increase the intensity of light incident on the photovoltaic units by using the design of “the first reflector faces and the second reflector faces reflecting and focusing light.” By this configuration, the cost of assembling the solar panel is reduced, improving the value of the solar devices.

The descriptions illustrated supra set forth simply the preferred embodiments of the present disclosure; however, the characteristics of the present disclosure are by no means restricted thereto. All changes, alternations, or modifications conveniently considered by those skilled in the art are deemed to be encompassed within the scope of the present disclosure delineated by the following claims.

What is claimed is:

1. A solar-power enhancing module comprising:
a base plate; and
a plurality of photovoltaic units disposed on the base plate, and including:
a solar panel;
a pair of first reflector boards disposed respectively at two opposite sides of the solar panel, and each having a first reflector face at the front thereof; and
a pair of second reflector boards disposed respectively at two opposite sides of the solar panel, and each having a second reflector face at the front thereof.

2. The solar-power enhancing module according to claim 1, wherein each of the first reflector boards and each of the second reflector boards are formed by a curved face, a flat face, or a combination of curved and flat faces.

3. The solar-power enhancing module according to claim 1, wherein each of the first reflector boards and each of the second reflector boards are formed by a plurality of small reflector boards or formed integrally as one body.

4. The solar-power enhancing module according to claim 1, wherein each of the photovoltaic units has a transparent cover.

5. The solar-power enhancing module according to claim 1, wherein the base plate is formed with a groove for draining water.

6. The solar-power enhancing module according to claim 1, wherein the height of each pair of the first reflector boards and the height of each pair of the second reflector boards are equal or not equal.

7. The solar-power enhancing module according to claim 1, wherein each of the first reflector boards and each of the second reflector boards are connected or have gaps therebetween.

8. The solar-power enhancing module according to claim 1, further comprising a battery unit electrically connected to each solar panels for storing electrical energy produced by the plurality of photovoltaic units.

9. The solar-power enhancing module according to claim 8, wherein each of the solar panels and the battery unit have a valve therebetween allowing flow of current in one direction for preventing the electric energy stored in the battery unit from flowing to the solar panels.

10. A sun tracking system having a solar-power enhancing module, comprising:
at least one solar-power enhancing module including:
a base plate;
a plurality of photovoltaic units disposed on the base plate, and including:
a solar panel;
a pair of first reflector boards disposed respectively at two opposite sides of the solar panel, and each having a first reflector face at the front thereof; and
a pair of second reflector boards disposed respectively at two opposite sides of the solar panel, and each having a second reflector face at the front thereof;
a sun tracking system including:
a support unit fixed on a surface;
a carrying unit disposed on the support unit for carrying the at least one solar-power enhancing module; and
at least one drive unit disposed on the support unit configured to rotate the carrying unit and the support unit.
